(19) United States
(12) Patent Application Publication
(10) Pub. No.: US 2013/0193807 A1
(43) Pub. Date: Aug. 1, 2013

(54) QUARTZ CRYSTAL VIBRATING PIECE AND QUARTZ CRYSTAL DEVICE

(71) Applicant: NIHON DEMPA KOGYO CO., LTD., Tokyo (JP)

(72) Inventor: Shuichi Mizusawa, Saitama (JP)

(73) Assignee: NIHON DEMPA KOGYO CO., LTD., Tokyo (JP)

(21) Appl. No.: 13/721,025

(22) Filed: Dec. 20, 2012

(30) Foreign Application Priority Data
Jan. 31, 2012 (JP) 2012-017415

(51) Int. Cl. H01L 41/18; H01L 41/053

(52) U.S. Cl. CPC H01L 41/18; H01L 41/053
USPC 310/351; 310/361

(57) ABSTRACT

An AT-cut quartz crystal vibrating piece with an excitation unit is in a rectangular shape. The quartz crystal vibrating piece includes a framing body, a connecting portion, a pair of excitation electrodes, and a pair of extraction electrodes. The excitation unit has a long side that is rotated at 61° or 119° with respect to the crystallographic axis X. The framing body has a long side that extends in 61° or 119° direction with respect to the crystallographic axis X. The connecting portion extends in 61° or 119° direction with respect to the crystallographic axis X. The connecting portion is perpendicular to a short side of the excitation unit and a short side of the framing body.

### CROSS-REFERENCE TO RELATED APPLICATION

This application claims the priority benefit of Japan application serial no. 2012-017415, filed on Jan. 31, 2012. The entirety of the above-mentioned patent application is hereby incorporated by reference herein and made a part of this specification.

### TECHNICAL FIELD

This disclosure relates to a quartz crystal vibrating piece that excites a thickness shear vibration and a quartz crystal device that includes the quartz crystal vibrating piece.

### DESCRIPTION OF THE RELATED ART

In a quartz crystal device which uses an AT-cut quartz-crystal vibrating piece, stress is directly applied to its base substrate. A stress may be also applied to the quartz crystal vibrating piece by thermal expansion or similar cause. Stress applied to the quartz crystal vibrating piece affects an oscillation frequency. This results in negative effects to various characteristics such as an aging characteristic and a frequency versus temperature characteristic. In view of this, Japanese Unexamined Patent Application Publication No. 2007-243681 (hereinafter referred to as Patent Literature 1) proposes a disclosure to prevent transmission of stress that affects an oscillation frequency.

Patent Literature 1 discloses a quartz crystal vibrating piece mounted in a quartz crystal device. The quartz crystal vibrating piece includes two supporting electrodes on a straight line that has a predetermined rotation angle with respect to a specific crystallographic axis. Specifically, an AT-cut quartz-crystal vibrating piece according to Patent Literature 1 includes at least one pair of connecting portions. This pair of connecting portions is on a straight line that has a rotation angle of 60° or 120° with respect to an X axis, which is a crystallographic axis of the AT-cut quartz-crystal vibrating piece. This pair of connecting portions connects a framing body and a vibrating piece together. The AT-cut quartz-crystal vibrating piece includes a pair of extraction electrodes disposed at the respective connecting portions. If stress is applied along the straight line having this rotation angle, a sensitivity ratio is extremely small. Thus, the AT-cut quartz-crystal vibrating piece has an extremely small effect in an oscillation frequency by the stress.

However, assume that the AT-cut quartz-crystal vibrating piece disclosed in Patent Literature 1 is formed by wet-etching. Since only the connecting portion is inclined with respect to the framing body or the AT-cut quartz-crystal vibrating piece, an acute angle region between the connecting portion and the framing body or an acute angle region between the connecting portion and the AT-cut quartz-crystal vibrating piece are not precisely finished actually.

A need thus exists for a quartz crystal vibrating piece and a quartz crystal device which are not susceptible to the drawback mentioned above.

### SUMMARY

According to a first aspect of this disclosure, there is provided a quartz crystal vibrating piece using an AT-cut quartz-crystal vibrating piece with an excitation unit in a rectangular shape. The excitation unit has a crystallographic axis X, a crystallographic axis Y′, and a crystallographic axis Z′. The quartz crystal vibrating piece includes a framing body, a connecting portion, a pair of excitation electrodes, and a pair of extraction electrodes. The framing body is disposed around the excitation unit across a predetermined void. The connecting portion connects the excitation unit and the framing body together. The pair of excitation electrodes is disposed on both principal surfaces of the excitation unit. The pair of extraction electrodes extends from the excitation unit to the framing body via the connecting portion. The excitation unit has a long side that is rotated at 61° or 119° with respect to the crystallographic axis X. The framing body has a long side that extends in 61° or 119° direction with respect to the crystallographic axis X. The connecting portion extends in 61° or 119° direction with respect to the crystallographic axis X. The connecting portion is perpendicular to a short side of the excitation unit and a short side of the framing body.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a first quartz crystal device 100;

FIG. 2A is a cross-sectional view of the first quartz crystal device 100;

FIG. 2B is a plan view of a quartz crystal vibrating piece 30;

FIG. 3A is a cross-sectional view of the quartz crystal vibrating piece 30;

FIG. 3B is a cross-sectional view of a typical modification of a quartz crystal vibrating piece 30A;

FIGS. 4A to 4D illustrate a flowchart of a method for fabricating the quartz crystal vibrating piece 30;

FIGS. 5A to 5D illustrate a flowchart of the method for fabricating the quartz crystal vibrating piece 30;

FIG. 6 is a plan view of a quartz-crystal wafer 30W;

FIG. 7 is a plan view of a lid wafer 10W;

FIG. 8 is a plan view of a base wafer 20W;

FIG. 9 is an exploded perspective view of a second quartz crystal device 200;

FIG. 10A is a cross-sectional view of a second quartz crystal device 200;

FIG. 10B is a plan view of a quartz crystal vibrating piece 230;

FIG. 11A is a plan view of a typical modification of a quartz crystal vibrating piece 230A;

FIG. 11B is a plan view of a typical modification of a quartz crystal vibrating piece 230B; and

FIG. 12 is a plan view of a quartz-crystal wafer 230W.

### DETAILED DESCRIPTION

A preferred embodiment disclosed here will be explained with reference to the attached drawings. It will be understood that the scope of the disclosure is not limited to the described embodiments, unless otherwise stated.

### Configuration of a First Quartz Crystal Device 100 of a First Embodiment

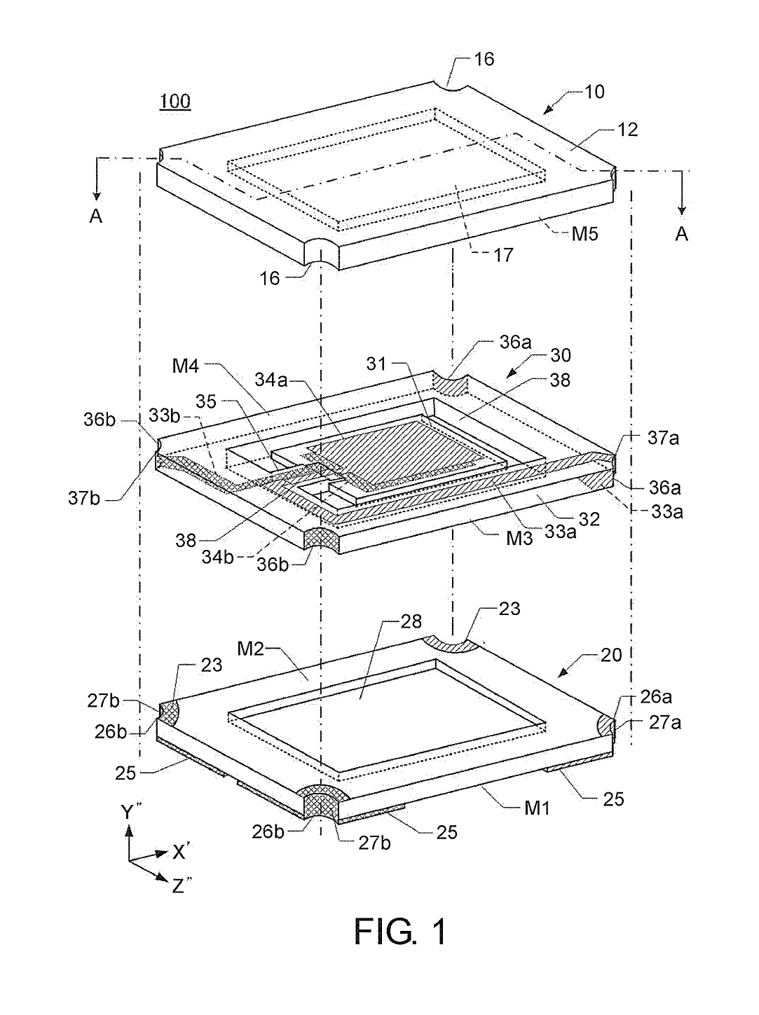

FIG. 1 is an exploded perspective view of a first quartz crystal device 100. The first quartz crystal device 100 includes a lid plate 10, a base plate 20, and a quartz crystal vibrating piece 30. The quartz crystal vibrating piece 30 employs an AT-cut quartz-crystal vibrating piece. The AT-cut quartz-crystal vibrating piece has a principal surface (in the Y-Z plane) that is tilted by 35° 15′ about the Y-axis of crystallographic axes (XYZ) of a synthetic quartz crystal in the direction from the Z-axis to the Y-axis around the X-axis. In this description, the new axes tilted with reference to the axis directions of the AT-cut quartz-crystal vibrating piece are denoted as the X axis, the Y′ axis, and the Z′ axis.

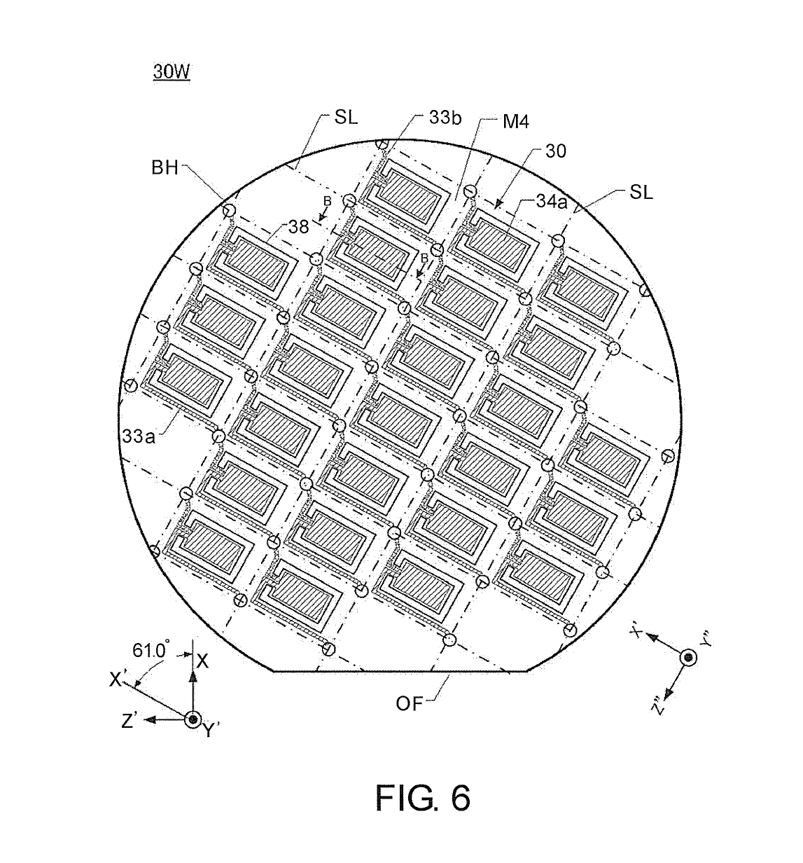

Further, the long sides of the lid plate 10, the base plate 20, and the quartz crystal vibrating piece 30 according to the first embodiment are rotated at 61° or 119° with respect to the crystallographic axis X with reference to the Y′ axis (see FIGS. 6 to 8). In the first embodiment described below, a direction inclined at 61° with respect to the crystallographic axis X is denoted as X′. Further, axis directions perpendicular to the X′ axis are denoted as Y″ axis and Z″ axis. Therefore, in description of the first quartz crystal device 100, the longitudinal direction of the first quartz crystal device 100 is referred as the X′ axis direction, the height direction of the first quartz crystal device 100 is referred as the Y″ axis direction, and the direction perpendicular to the X′ axis and Y″ axis directions is referred as the Z″ axis direction.

The quartz crystal vibrating piece 30 includes an excitation unit 31, a framing portion 32, and a connecting portion 35. The excitation unit 31 vibrates at a predetermined vibration frequency. The framing portion 32 surrounds the excitation unit 31. The connecting portion 35 connects the excitation unit 31 and the framing portion 32 together. Regions between the excitation unit 31 and the framing portion 32 has a through hole 38 that passes through the quartz crystal vibrating piece 30 in the Y″ axis direction. Excitation electrodes 34a and 34b are formed on surfaces of the +Y″ axis side and the −Y″ axis side of the excitation unit 31. Extraction electrodes 33a and 33b are extracted from respective excitation electrodes 34a and 34b through a connecting portion 35 to the framing portion 32. The framing portion 32 includes castellations 36a and 36b on side surfaces at four corners. Side-surface electrodes 37a and 37b are formed on the castellations 36a and 36b.

The base plate 20 employs an AT-cut quartz-crystal material, and is arranged at the −Y″ axis side of the quartz crystal vibrating piece 30. The base plate 20 is formed in a rectangular shape that has long sides in the X′ axis direction and short sides in the Z″ axis direction. A pair of mounting terminals 25 are formed on a surface of the −Y″ axis side of the base plate 20. The mounting terminals 25 are soldered, fixed, and electrically connected to a printed circuit board or similar member. This mounts the first quartz crystal device 100 to a printed circuit board or similar member. The base plate 20 includes castellations 26a and 26b on side surfaces at four corners. The castellations 26a and 26b include side-surface electrodes 27a and 27b. The base plate 20 includes a depressed portion 28 that is depressed on a surface of the +Y″ axis side. A bonding surface M2 to be bonded to a framing portion 32 is formed in a peripheral area of the depressed portion 28. Connecting electrodes 23 are formed at four corners on the bonding surface M2 in a peripheral area of the castellations 26. The connecting electrodes 23 are electrically connected to the mounting terminals 25 via the side-surface electrodes 27a and 27b formed on the castellations 26. In the case where the quartz crystal vibrating piece 30 does not contact the base plate 20, the depressed portion 28 may be eliminated.

The lid plate 10 employs an AT-cut quartz-crystal material, and is arranged at the +Y″ axis side of the quartz crystal vibrating piece 30. The lid plate 10 includes a depressed portion 17 on a surface of the −Y″ axis side. A bonding surface M5 is formed in a peripheral area of the depressed portion 17. In the case where the quartz crystal vibrating piece 30 does not contact the lid plate 10, the depressed portion 17 may be eliminated.

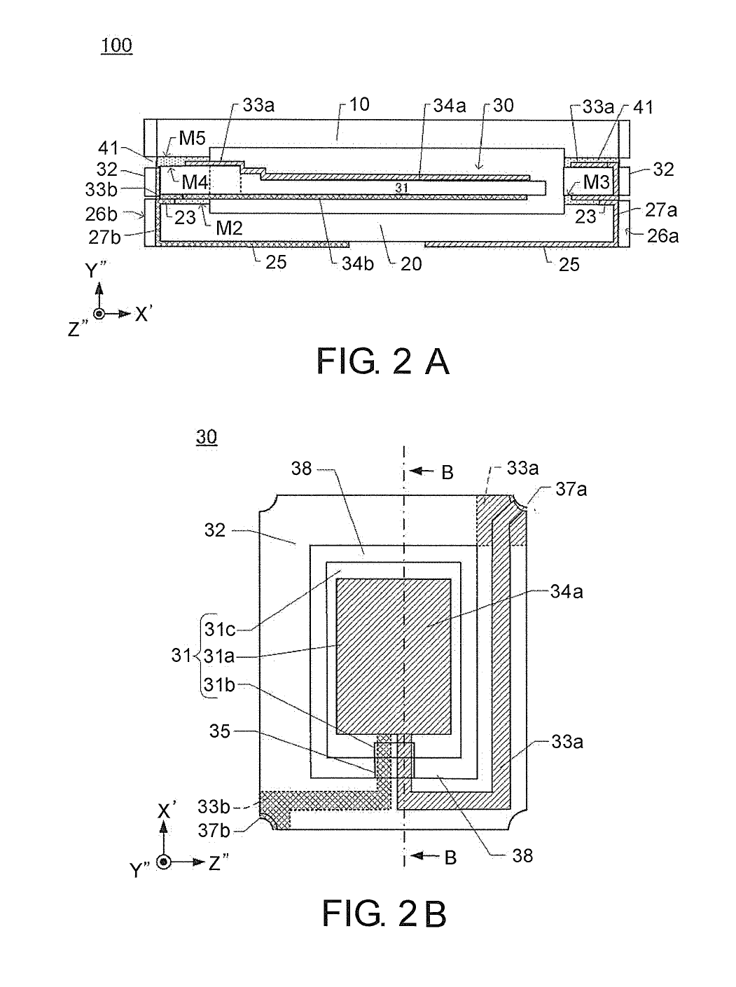

FIG. 2A is a cross-sectional view of a first quartz crystal device 100. FIG. 2A is a cross-sectional view taken along the line A-A of FIG. 1. The bonding surface M5 of the lid plate 10 is bonded to a bonding surface M4 at the +Y″ axis side of the framing portion 32 in the quartz crystal vibrating piece 30 via a bonding material 41. The bonding surface M2 of the base plate 20 is bonded to a bonding surface M3 at the −Y″ axis side of the framing portion 32 via the bonding material 41. When the framing portion 32 of the quartz crystal vibrating piece 30 is bonded to the bonding surface M2 of the base plate 20, the extraction electrodes 33a and 33b, which are formed on the bonding surface M3 at the −Y″ axis side of the framing portion 32 (see FIG. 1), are electrically connected to the connecting electrodes 23, which are formed on the bonding surface M2 of the base plate 20. Accordingly, the excitation electrodes 34a and 34b are electrically connected to the mounting terminals 25 via the extraction electrodes 33a and 33b, the connecting electrodes 23, and the side-surface electrodes 27a and 27b. For example, the bonding material 41 employs polyimide-based non-conductive resin or non-conductive low-melting-point glass.

FIG. 2B is a plan view of the quartz crystal vibrating piece 30. The excitation unit 31 is formed in a rectangular shape. The framing portion 32 is formed of two long sides and two short sides to surround the excitation unit 31. One connecting portion 35 connects the excitation unit 31 and the framing portion 32 together. The one connecting portion 35 is formed at the center of the short side at the −X′ axis side of the excitation unit 31, then extends in the −X′ axis direction, and connects to the short side of the framing portion 32. The excitation unit 31 includes a first region 31a, a second region 31b, and a third region 31c. The first region 31a includes excitation electrodes 34a and 34b in the X′ axis direction. The second region 31b directly connects to the connecting portion 35. The third region 31c is a region other than the first region 31a and the second region 31b. The second region 31b forms a level difference surface that connects to the connecting portion 35. Although not illustrated in this embodiment, the first region 31a may have a mesa structure that has an energy confinement effect and a large thickness in the Y″ direction.

The one connecting portion 35 is perpendicular to the short side of the excitation unit 31 and the short side of the framing portion 32. Accordingly, the connecting portion 35 is precisely formed in a 61° or 119° direction with respect to the crystallographic axis X by a method for fabricating the quartz crystal vibrating piece 30 described below.

The extraction electrode 33a is extracted from the excitation electrode 34a formed on a surface of the +Y″ axis side to the −X′ axis side of the framing portion 32 through the second region 31b and the connecting portion 35. The extraction electrode 33b is extracted from the excitation electrode 34b formed on a surface of the −Y″ axis side to the −X′ axis side of the framing portion 32 through the second region 31b and the connecting portion 35. When viewed from the Y″ axis direction, the extraction electrode 33a and the extraction electrode 33b do not overlap with each other within the second region 31b and the connecting portion 35.

The extraction electrode 33a, which is extracted to the framing portion 32, extends to the +Z″ axis of the framing portion 32 and further extends in the +X′ axis direction to the side-surface electrode 37a. Additionally, the extraction electrode 33a is extracted from the +Y″ axis side to the −Y″ axis side surface through the side-surface electrode 37a. The extraction electrode 33b, which is extracted to the framing portion 32, extends in the −Z″ axis direction and further extends up to a corner portion on a surface of the framing portion 32 in the −Y″ axis side.

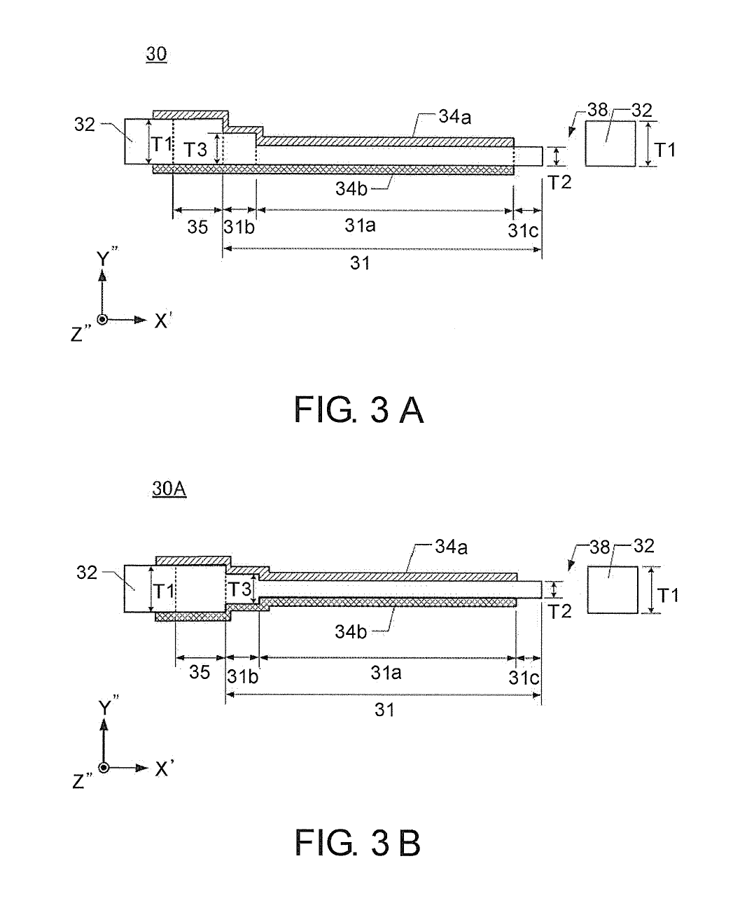

FIG. 3A is a cross-sectional view of the quartz crystal vibrating piece 30. FIG. 3A is a cross-sectional view taken along the line B-B of FIG. 2B. The quartz crystal vibrating piece 30 has a first thickness T1 in the Y″ axis direction of the framing portion 32 and the connecting portion 35, and a second thickness T2 in the Y″ axis direction of the excitation unit 31. The second region 31b (see FIG. 2B) includes a level difference surface. The level difference surface increases in thickness from the second thickness T2 of the excitation unit 31 to the thickness T1 of the connecting portion 35. The level difference surface connects the excitation unit 31 to the framing portion 32. With the quartz crystal vibrating piece 30, for example, the first thickness T1 is 100 μm, and the second thickness T2 is adjusted corresponding to a vibration frequency. The second region 31b, which is a level difference surface, reduces stress transmission from the connecting portion 35 to the excitation unit 31 and also reduces disconnection of the extraction electrode 33a.

FIG. 3B is a cross-sectional view of a typical modification of a quartz crystal vibrating piece 30A. In FIG. 3A, the level difference surface is formed only on a surface side of the +Y″ axis side. However, the quartz crystal vibrating piece 30A may include the level difference surfaces on both of front and back surfaces of the second region 31b. In the quartz crystal vibrating piece 30A, the same reference numerals are assigned for structural parts similar to those of the quartz crystal vibrating piece 30.

In the quartz crystal vibrating piece 30 and the quartz crystal vibrating piece 30A, the connecting portions 35 and the framing portion 32 have the same thickness T1 and thus have high rigidity. The connecting portion 35 extends in a 61° or 119° direction with respect to the crystallographic axis X and thus have an extremely small stress sensitivity. Additionally, the second region 31b forms a level difference surface so as to avoid an extreme change in thickness from the thickness T1 of the connecting portion 35 to the thickness T2 of the excitation unit 31. Accordingly, the excitation unit 31 is less affected in a frequency variation due to impact from outside or similar.

### A Method for Fabricating the Quartz Crystal Vibrating Piece 30

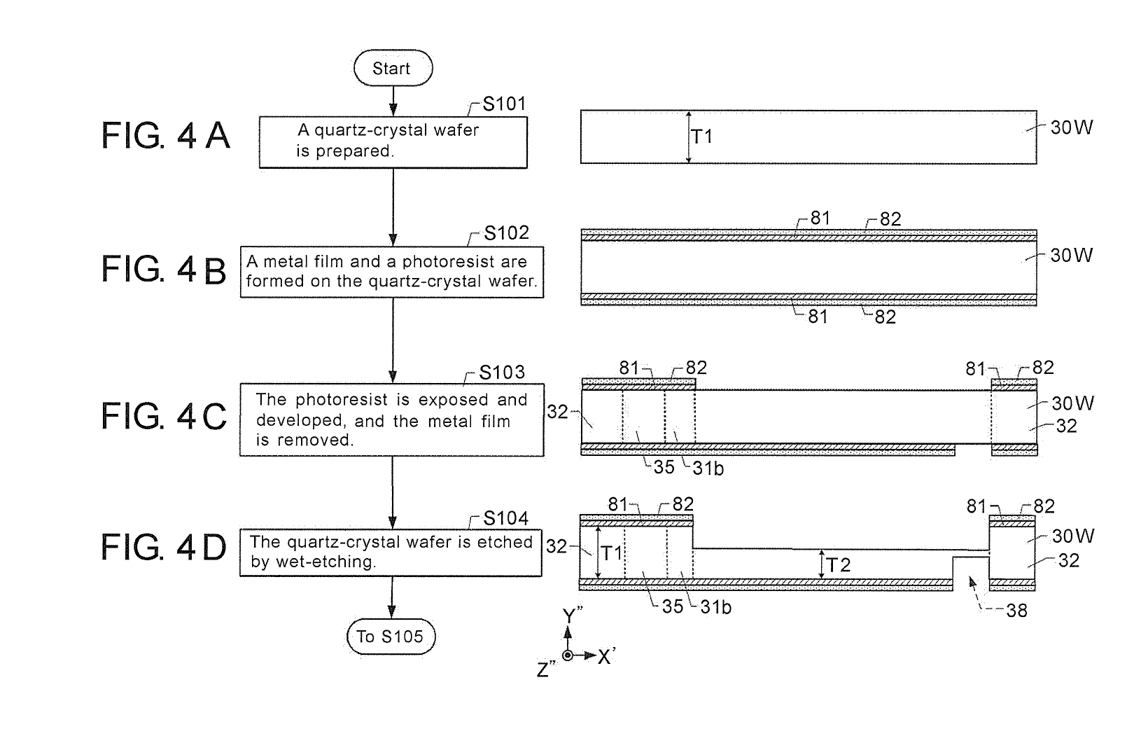

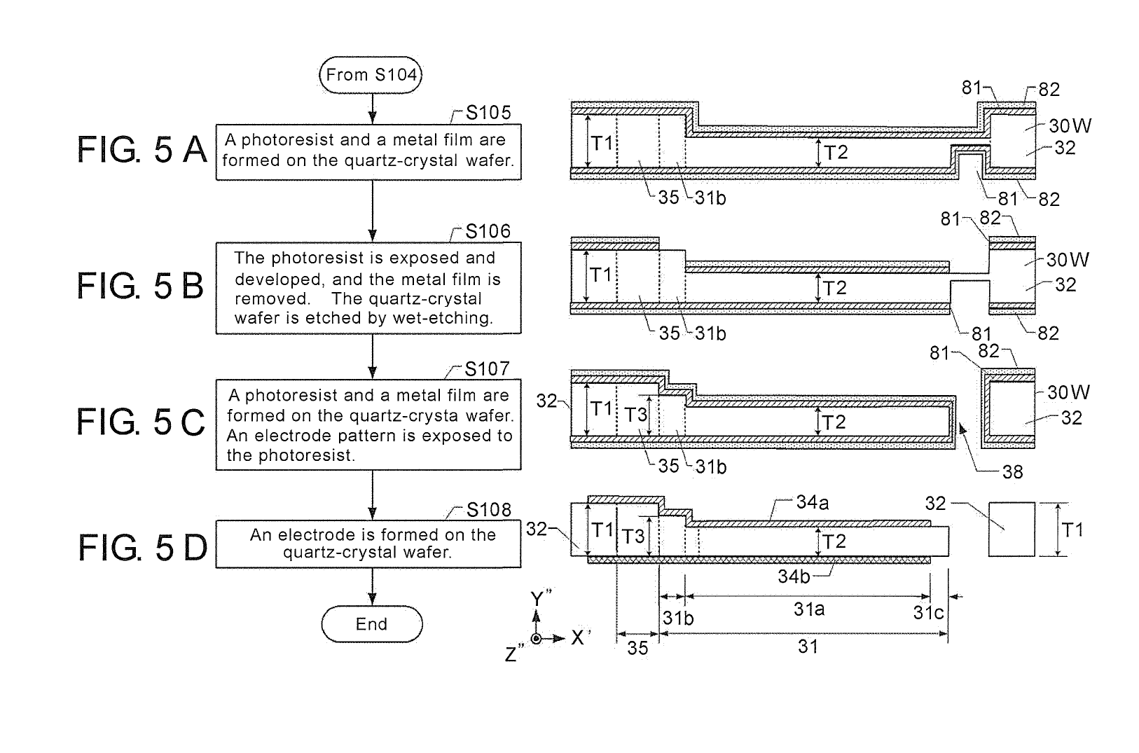

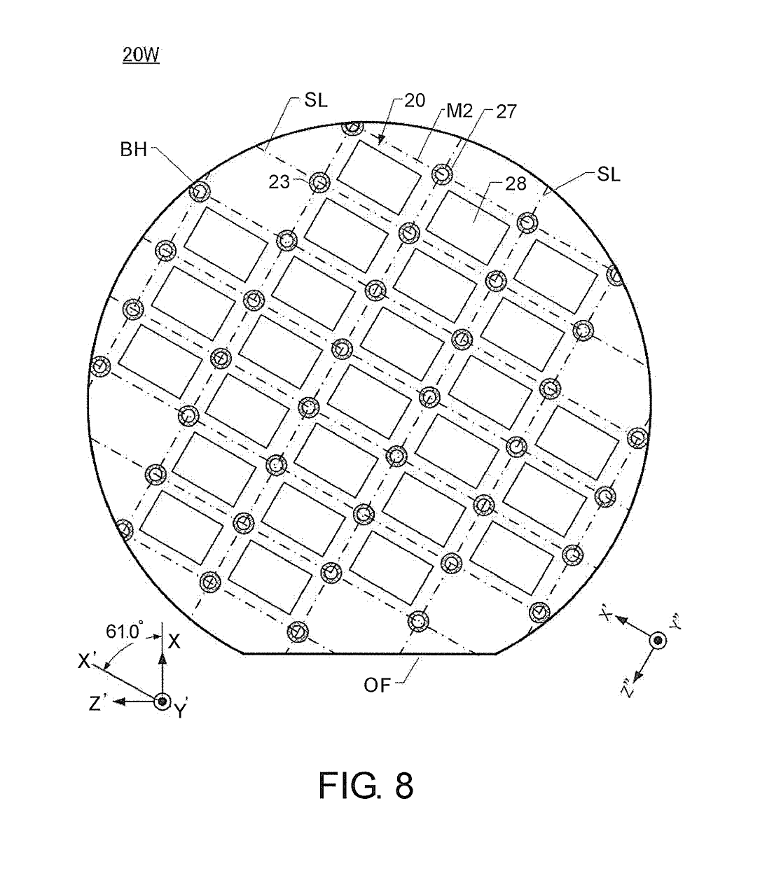

The method for fabricating the quartz crystal vibrating piece 30 will be described with referring to the flowcharts illustrated in FIGS. 4A to 4D and 5A to 5D. At the right side of the flowchart in FIGS. 4A to 4D and 5A to 5D, views for describing respective steps in FIGS. 4A to 4D and 5A to 5D are illustrated. These drawings are cross-sectional views corresponding to a cross-sectional surface taken along the line B-B of the quartz crystal vibrating piece 30 (see FIG. 2B) illustrated in the quartz crystal vibrating piece 30 (see FIG. 8) of a quartz-crystal wafer 30W where a plurality of quartz crystal vibrating pieces 30 is formed.

FIGS. 4A to 4D illustrate a flowchart of a method for fabricating the quartz crystal vibrating piece 30. At the right side of respective steps in the flowchart, FIGS. 4A to 4D for describing the respective steps are illustrated. FIGS. 4A to 4D are partial cross-sectional views of the quartz-crystal wafer 30W.

At Step S101, the quartz-crystal wafer 30W is prepared. FIG. 4A is a partial cross-sectional view of the quartz-crystal wafer 30W. The quartz-crystal wafer 30W made of a quartz-crystal material is polished to make the surfaces of the +Y″ axis side and the −Y″ axis side flat. The quartz-crystal wafer 30W is formed to have the first thickness T1 in the Y″ axis direction.

At step S102, a metal film 81 and a photoresist 82 are formed on the quartz-crystal wafer 30W. At step S102, first, the metal film 81 is formed on the surfaces of the +Y″ axis side and the −Y″ axis side of the quartz-crystal wafer 30W by a sputtering or a vacuum evaporation. The metal film 81, for example, is formed by formation of a chromium (Cr) layer on the quartz-crystal wafer 30W, and formation of a gold (Au) layer evaporated on the surface of the chromium layer. Additionally, a photoresist 82 is formed on the surface of the metal film 81.

At step S103, the photoresist 82 is exposed and developed, and the metal film 81 is removed. FIG. 4C is a partial cross-sectional view of the quartz-crystal wafer 30W where the photoresist 82 is exposed and developed, and the metal film 81 is removed.

At step S103, as understood from FIG. 6, a mask with an outer shape of the quartz crystal vibrating piece 30 is placed in a direction rotated at 61° with respect to the X axis of the quartz-crystal wafer 30W (the mask is not shown). The masks are disposed on both surfaces of the +Y″ axis and the −Y″ axis sides of the quartz-crystal wafer 30W. The mask disposed at the +Y″ axis has opening windows in regions corresponding to the excitation unit 31, a through hole 38, and a through hole BH for castellation in the quartz crystal vibrating piece 30. The mask disposed at the −Y″ axis has opening windows in regions corresponding to the through hole 38 and the through hole BH (see FIG. 6). The outer shape of the quartz crystal vibrating piece 30 is exposed to the photoresist 82 via the mask. Then, the photoresist 82 is developed, and the metal film 81 formed on the region where the photoresist 82 has been developed is removed.

At step S104, the quartz-crystal wafer 30W is etched by wet-etching. FIG. 4D is a partial cross-sectional view of the quartz-crystal wafer 30W after the wet-etching is performed in step S104. The quartz-crystal wafer 30W is etched by wet-etching in a region where the photoresist 82 and the metal film 81 have been removed in step S103. The wet-etching of the surface at the +Y″ axis side of the quartz-crystal wafer 30W forms a thickness of the quartz-crystal wafer 30W in a region where wet-etching has been performed to be a second thickness T2. A region where wet-etching has not been performed in the quartz-crystal wafer 30W includes the framing portion 32, the connecting portion 35, and a similar member. The thicknesses of these regions in the Y″ axis direction remain in the first thickness T1. In FIG. 4D, the through hole 38 of the quartz crystal vibrating piece 30 does not pass through. However, the through hole 38 of the quartz crystal vibrating piece 30 may be formed at step S104, depending on an amount of the wet-etching that reduces in thickness from the first thickness T1 to the second thickness T2.

FIGS. 5A to 5D illustrate a flowchart of the method for fabricating the quartz crystal vibrating piece 30. The flowchart in FIGS. 5A to 5D illustrates a procedure subsequent to the procedure in FIGS. 4A to 4D. At the right side of respective steps in the flowchart, FIGS. 5A to 5D are illustrated for describing the respective steps.

At step S105, the photoresist 82 and the metal film 81 are formed on the quartz-crystal wafer 30W. Step S105 is a step subsequent to step S104 in FIGS. 4A to 4D. FIG. 5A is a partial cross-sectional view of the quartz-crystal wafer 30W with the photoresist 82 and the metal film 81. At step S105, the photoresist 82 and the metal film 81 formed on the quartz-crystal wafer 30W are all removed. After that, the metal film 81 and the photoresist 82 are formed again on the surfaces of the +Y″ axis side and the −Y″ axis side of the quartz-crystal wafer 30W.

At step S106, the photoresist 82 is exposed and developed, and the metal film 81 is removed. Then, the quartz-crystal wafer 30W is etched by wet-etching. FIG. 5B is a partial cross-sectional view of the quartz-crystal wafer 30W where the metal film 81 is removed. At step S106, first, exposure is performed on a region corresponding to the second region 31b of the excitation unit 31, and regions corresponding to the through hole 38 and the through hole BH (see FIG. 6) of the quartz-crystal wafer 30W at the +Y″ axis side. Exposure is performed on regions corresponding to the through hole 38 and the through hole BH of the quartz-crystal wafer 30W at the −Y″ axis side.

Further, the photoresist 82 is exposed, and the metal film 81 in the removed region is removed. Then, the quartz-crystal wafer 30W is etched by wet-etching. This forms a level difference surface on the second region 31b of the excitation unit 31 of the quartz-crystal wafer 30W, and makes the through hole 38 and the through hole BH (see FIG. 6) pass through. After that, the photoresist 82 and the metal film 81 remaining on the quartz-crystal wafer 30W are all removed.

At step S107, the metal film 81 and the photoresist 82 for forming an electrode are formed on the surfaces of the +Y″ axis side and the −Y″ axis side of the quartz-crystal wafer 30W again. FIG. 5C is a partial cross-sectional view of the quartz-crystal wafer 30W where the photoresist 82 and the metal film 81 are formed. After that, exposure and development are performed on the photoresist 82 formed at regions corresponding to the through hole 38 of the quartz-crystal wafer 30W at the +Y″ axis side and the −Y″ axis side, thus removing the metal film 81 formed in the region where the photoresist 82 has been developed.

At step S108, electrodes are disposed on the quartz-crystal wafer 30W. FIG. 5D is a partial cross-sectional view of the quartz-crystal wafer 30W where the electrodes are formed. At step S108, the excitation electrodes 34a and 34b and the extraction electrodes 33a and 33b are formed in the quartz-crystal wafer 30W.

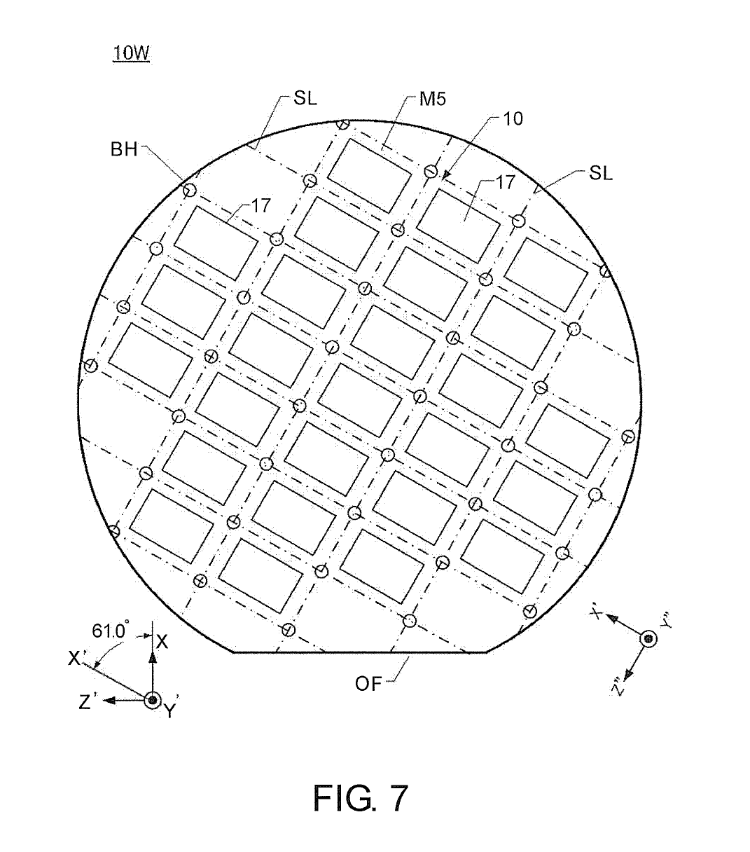

As described above, a plurality of quartz crystal vibrating pieces 30 is formed on the quartz-crystal wafer 30W. After step S108, the quartz-crystal wafer 30W is bonded to the lid wafer 10W (see FIG. 7) and the base wafer 20W (see FIG. 8) via the bonding material 41 (see FIG. 2A). Each wafer is positioned using an orientation flat (OF).

The lid wafer 10W is made of an AT-cut quartz-crystal material. As illustrated in FIG. 7, the lid wafer 10W includes a plurality of lid plates 10. Each of the plurality of lid plates 10 has a depressed portion 17. The bonding surface M5 is formed in a peripheral area of the depressed portion 17.

The base wafer 20W is made of an AT-cut quartz-crystal material. As illustrate in FIG. 8, the base wafer 20W includes a plurality of base plates 20. Each of the plurality of base plates 20 includes a depressed portion 28. The bonding surface M2 is formed in a peripheral area of the depressed portion 28. The connecting electrode 23 is formed around the through hole BH on the bonding surface M2. Additionally, at the inner peripheral of the through hole BH, the side-surface electrodes 27a and 27b are formed.

After the lid wafer 10W, the quartz-crystal wafer 30W, and the base wafer 20W are bonded with the bonding material 41, dicing is performed along scribe lines SL illustrated in FIGS. 6 to FIG. 8. Dicing into individual chips forms the first quartz crystal devices 100. The through hole BH is divided into quarters, and each of the divided hole becomes a castellation. The lid plate 10, the quartz crystal vibrating piece 30, and the base plate 20 are made of an AT-cut quartz-crystal material, and each long side direction of them is inclined at 61° (or 119°) with respect to the X axis. Accordingly, the lid plate 10, the quartz crystal vibrating piece 30, and the base plate 20 have the same thermal expansion, and the first quartz crystal device 100 does not crack even if a temperature varies substantially.

The lid plate 10, the quartz crystal vibrating piece 30, and the base plate 20 are inclined at 61° (or 119°) with respect to the X axis. After the first quartz crystal device 100 is mounted on a printed circuit board or similar, even if stress is applied to the first quartz crystal device 100 from outside due to an impact or similar, the stress is hard to be transmitted from the lid plate 10 or the base plate 20 to the excitation unit 31 via the connecting portion 35. In view of this, a frequency variation is hard to be generated in the excitation unit 31.

### Configuration of a Second Quartz Crystal Device 200 of a Second Embodiment

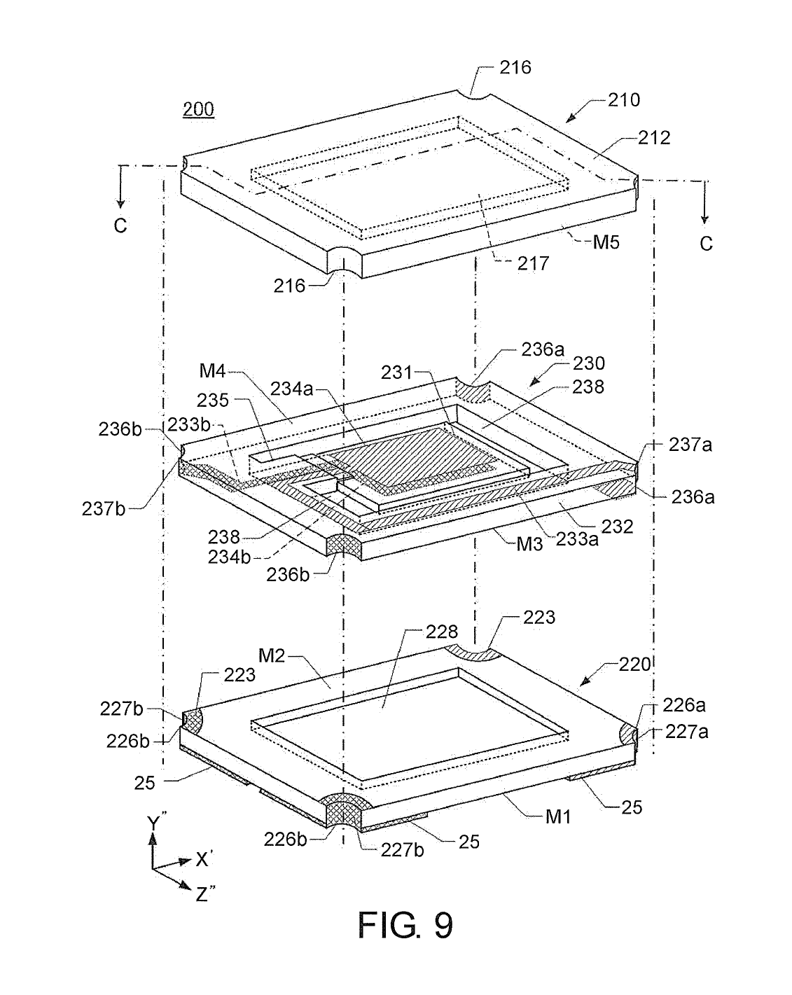

FIG. 9 is an exploded perspective view of a second quartz crystal device 200.

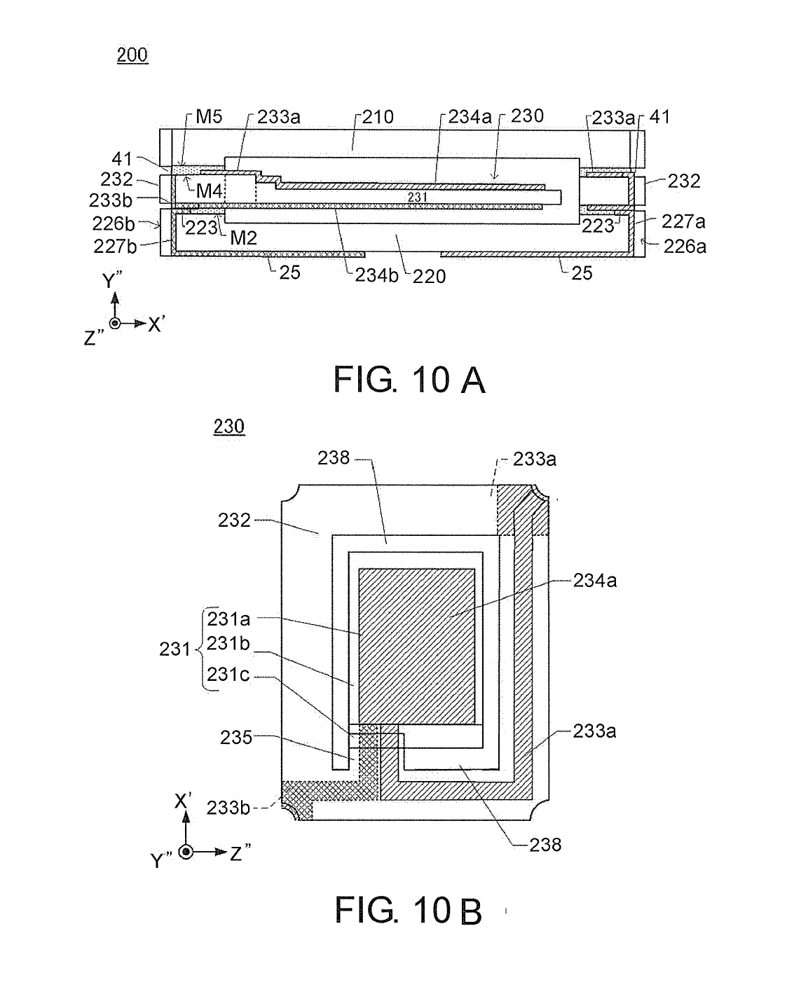

FIG. 10A is a cross-sectional view of the second quartz crystal device 200. FIG. 10B is a plan view of a quartz crystal vibrating piece 230. The second quartz crystal device 200 includes a lid plate 210 and a base plate 220 that are made of a glass, and the quartz crystal vibrating piece 230. The quartz crystal vibrating piece 230 according to the second embodiment and the quartz crystal vibrating piece 30 according to the first embodiment differ in a connected position of the connecting portion. The second embodiment is otherwise similar to the first embodiment.

The long side of the quartz crystal vibrating piece 230 is formed to be rotated at 61° or 119° with respect to the crystallographic axis X and extends in the +X′ axis direction. The quartz crystal vibrating piece 230 includes an excitation unit 231, a framing portion 232, which surrounds the excitation unit 231, and one connecting portion 235, which connects the excitation unit 231 and the framing portion 232 together. The connecting portion 235 is formed at the −Z″ axis side of the short side at the −X′ axis side of the excitation unit 231, and extends from there to the −X′ axis direction to connect to the framing portion 232. Regions other than the connecting portion 235 between the excitation unit 231 and the framing portion 232 constitute a through hole 238. The through hole 238 passes through the quartz crystal vibrating piece 230 in the Y″ axis direction.

The excitation electrodes 234a and 234b are formed on the surfaces of +Y″ axis side and the −Y″ axis side of the excitation unit 231. The extraction electrodes 233a and 233b are extracted from the respective excitation electrodes 234a and 234b through a connecting portion 235 to the framing portion 232. The excitation unit 231 includes a first region 231a, a second region 231b, and a third region 231c. The first region 231a includes the excitation electrodes 234a and 234b in the X′ axis direction. The second region 231b directly connects to the connecting portion 235. The third region 231c is a region other than the first region 231a and the second region 231b. The second region 231b forms a level difference surface connected to the connecting portion 235.

Stress from the connecting portion 235 has a nature where the stress is transmitted from the connecting portion in the +X′ axis direction. In the case where the long side has a 61° angle with respect to the crystallographic axis X, a stress sensitivity coefficient becomes approximately zero. However, since the long side may not be precisely formed in the +X′ axis direction, realistically, stress may be applied slightly. As the quartz crystal vibrating piece 30 according to the first embodiment, in the case where the connecting portion 35 is at the center of the quartz crystal vibrating piece 30, stress is transmitted to the center portion of the excitation electrode. This may cause a frequency variation. With the quartz crystal vibrating piece 230 according to the second embodiment, the connecting portion 235 is formed at the end portion in the −Z″ axis of the quartz crystal vibrating piece 230, the stress is transmitted to the end portion of the excitation electrode and hard to be transmitted to the center portion of the excitation electrode. This reduces frequency variation.

### A Method for Fabricating the Quartz Crystal Vibrating Piece 230

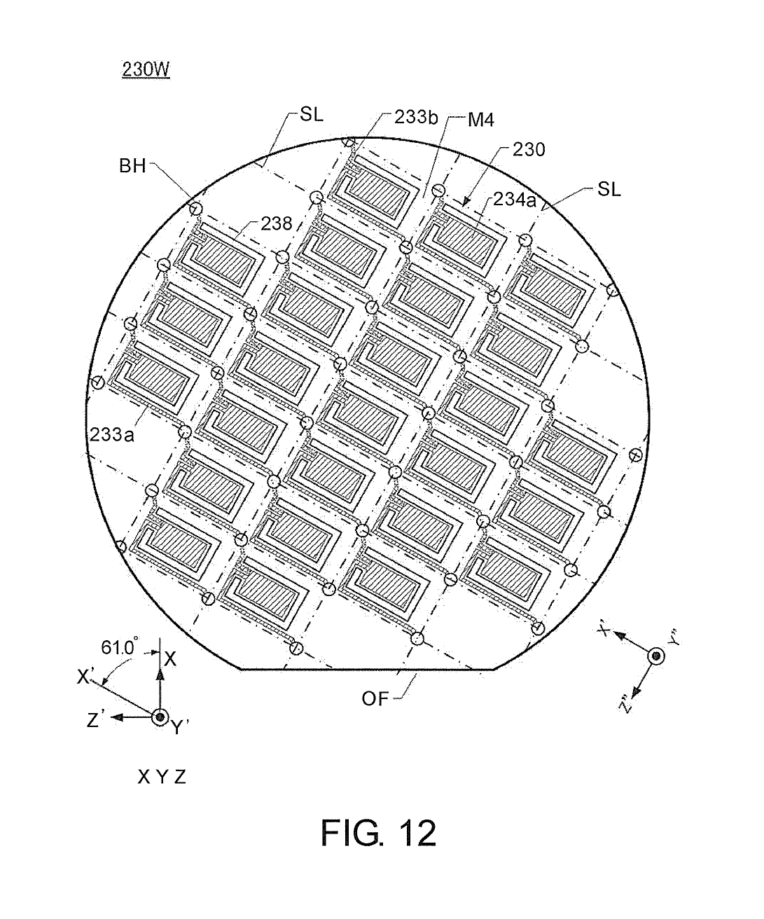

The method for fabricating the quartz crystal vibrating piece 230 is almost the same as the method illustrated in the flowchart in FIGS. 4A to 4D and 5A to 5D. The quartz crystal vibrating piece 230 is formed in a direction rotated at 61° with respect to the X axis of the quartz-crystal wafer 230W (see FIG. 12).

### Other Typical Modifications

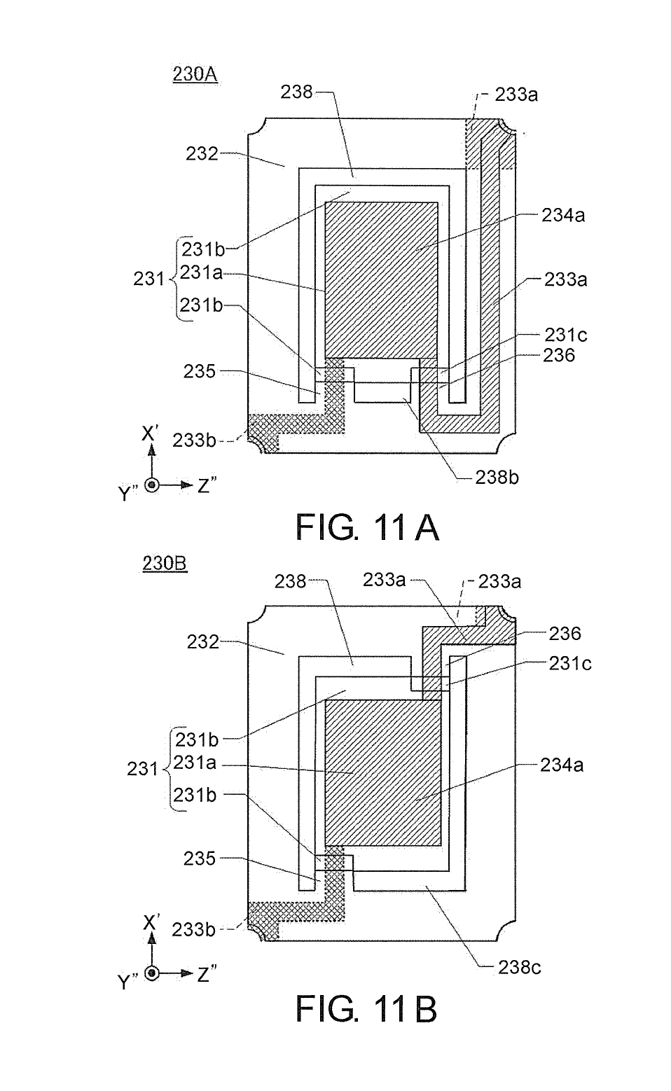

FIG. 11A is a plan view of typical first Modification of a quartz crystal vibrating piece 230A. FIG. 11B is a plan view of typical second Modification of a quartz crystal vibrating piece 230B. Like reference numerals designate corresponding or identical elements of the quartz crystal vibrating piece 230.

The quartz crystal vibrating piece 230A and the quartz crystal vibrating piece 230B have long sides rotated at 61° or 119° with respect to the crystallographic axis X, and extend to the +X′ axis direction of a new crystallographic axis. The quartz crystal vibrating piece 230A and the quartz crystal vibrating piece 230B each have two connecting portions. The quartz crystal vibrating piece 230A includes the connecting portion 235 and a connecting portion 236 at respective both ends of the −X′ axis side. Stress is transmitted to the both end portions of the excitation unit 231 and hard to be transmitted to the center portion of the excitation electrodes 234a and 234b. The quartz crystal vibrating piece 230B includes the connecting portion 235 and the connecting portion 236 at respective both ends of the −X′ axis side and +X′ axis side. Stress is transmitted to the both end portions of the excitation unit 231 and hard to be transmitted to the center portion of the excitation electrodes 234a and 234b, thus restricting a frequency variation.

Representative embodiments have been described in detail above. As evident to those skilled in the art, the disclosure may be changed or modified in various ways within the technical scope of the disclosure. For example, this disclosure is applicable to a crystal oscillator where an IC or similar that embeds an oscillation circuit is disposed on a base portion, as well as a crystal unit. While in the first and the second embodiments, a quartz crystal vibrating piece on a flat plate is disclosed, a mesa-type vibrating piece in a convex shape or an inverse mesa-type vibrating piece in a depressed shape may also be applicable.

While in this embodiment a quartz crystal vibrating piece is at a position rotated at 61° or 119° with respect to the crystallographic axis X, fabricating a quartz crystal vibrating piece at a rotation angle of 61°±5° or 119°±5°, which considers a fabrication error, provides the effect of this embodiment.

A quartz crystal vibrating piece according to a second aspect may have only one connecting portion. A pair of extraction electrodes is disposed at the one connecting portion not to overlap one another when viewed from a normal direction of the principal surfaces. In the quartz crystal vibrating piece according to a third aspect, a straight line that connects the one connecting portion and the center of the excitation electrodes may be in 61° or 119° direction with respect to the crystallographic axis X. In the quartz crystal vibrating piece of a fourth aspect, the framing body and the connecting portion may have a thickness in the Y′ axis direction that is thicker than a thickness of the excitation unit in the Y′ axis direction. In a quartz crystal vibrating piece according to a fifth aspect, a level difference surface is formed on a part of an excitation unit. The level difference surface may have thickness that changes from the thickness of the excitation unit to the thickness of the connecting portion.

A quartz crystal device according to a sixth aspect may include any of the quartz crystal vibrating pieces according to the first aspect to the fifth aspect. The quartz crystal device may include a base portion in a rectangular shape and a lid portion in a rectangular shape. The base portion is made of a glass material and bonds to one principal surface of the framing body. The lid portion is made of a glass material and bonds to another principal surface of the framing body. A quartz crystal device according to a seventh aspect may include any of the quartz crystal vibrating pieces according to the first aspect to the fifth aspect. The quartz crystal device may include a base portion in a rectangular shape and a lid portion in a rectangular shape. The base portion is made of an AT-cut crystal material and bonds to one principal surface of the framing body. The lid portion is made of an AT-cut crystal material and bonds to another principal surface of the framing body. The long sides of the base portion and the lid portion are rotated at 61° or 119° with respect to the crystallographic axis X.

With the quartz crystal vibrating piece and the quartz crystal device according to this disclosure, a variation in a frequency characteristic due to stress applied to a package and stress applied to an excitation unit by thermal expansion or similar force can be avoided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A quartz crystal vibrating piece using an AT-cut quartz-crystal vibrating piece with an excitation unit in a rectangular shape, the excitation unit having a crystallographic axis X, a crystallographic axis Y′, and a crystallographic axis Z′, the quartz crystal vibrating piece comprising:
a framing body, being disposed around the excitation unit across a predetermined void;
a connecting portion, connecting the excitation unit and the framing body together;
a pair of excitation electrodes, being disposed on both principal surfaces of the excitation unit; and
a pair of extraction electrodes, being extended from the excitation unit to the framing body via the connecting portion, wherein,
the excitation unit has a long side that is rotated at 61° or 119° with respect to the crystallographic axis X,
the framing body has a long side that extends in 61° or 119° direction with respect to the crystallographic axis X, and
the connecting portion extends in 61° or 119° direction with respect to the crystallographic axis X, the connecting portion being perpendicular to a short side of the excitation unit and a short side of the framing body.

2. The quartz crystal vibrating piece according to claim 1, wherein,
the number of the connecting portions is only one, and
the pair of extraction electrodes, which are disposed at the one connecting portion, are not overlapped with one another when viewed from a normal direction of the principal surface.

3. The quartz crystal vibrating piece according to claim 2, wherein,
a straight line that connects the one connecting portion and the center of the excitation electrode is in 61° or 119° direction with respect to the crystallographic axis X.

4. The quartz crystal vibrating piece according to claim 1, wherein,
the framing body and the connecting portion have a thickness in a Y′ axis direction that is thicker than a thickness of the excitation unit in the Y′ axis direction.

5. The quartz crystal vibrating piece according to claim 4, wherein,
a level difference surface is formed on a part of the AT-cut quartz-crystal vibrating piece, and
the level difference surface has thickness that changes from the thickness of the excitation unit to the thickness of the connecting portion.

6. A quartz crystal device, comprising:
the quartz crystal vibrating piece according to claim 1;
a base portion in a rectangular shape, the base portion being made of a glass material, the base portion being bonded to one principal surface of the framing body; and
a lid portion in a rectangular shape, the lid portion being made of a glass material, the lid portion being bonded to another principal surface of the framing body.

7. A quartz crystal device, comprising:
the quartz crystal vibrating piece according to claim 1;
a base portion in a rectangular shape, the base portion being made of an AT-cut crystal material, the base portion being bonded to one principal surface of the framing body;
a lid portion in a rectangular shape, the lid portion being made of an AT-cut crystal material, the lid portion being bonded to another principal surface of the framing body; and
the base portion and the lid portion each have a long side, the long side being rotated at 61° or 119° with respect to the crystallographic axis X.
